(19) United States
(12) Patent Application Publication
(10) Pub. No.: US 2026/0144042 A1
(43) Pub. Date: May 21, 2026

(54) INTEGRATED CIRCUIT DEVICE INCLUDING AN AIRGAP EXTENDING ON AN AXIS OF A METAL LINE AND METHOD OF FORMING THE SAME

(71) Applicant: SAMSUNG ELECTRONICS CO., LTD., Suwon-si (KR)

(72) Inventors: Johnsoo Kim, Clifton Park, NY (US); Wonkeun Chung, Clifton Park, NY (US); Sangshin Jang, Rexford, NY (US); Kang-ill Seo, Springfield, VA (US)

(21) Appl. No.: 19/361,541

(22) Filed: Oct. 17, 2025

Related U.S. Application Data
(60) Provisional application No. 63/721,109, filed on Nov. 15, 2024.

(51) Int. Cl. H01L 23/522; H01L 21/768; H01L 23/532

(52) U.S. Cl. CPC H10W 20/42; H10W 20/056; H10W 20/081; H10W 20/4441

(57) ABSTRACT

An integrated circuit device includes a first under mold layer and a second under mold layer each extending in a first direction and spaced apart from each other in a second direction, perpendicular to the first direction; an under metal line between the first under mold layer and the second under mold layer and extending in the first direction; an intermediate mold layer on the first under mold layer and the second under mold layer and separated from the under metal line by an air gap; and a via contact on the under metal line and extending through an opening in the intermediate mold layer, the via contact comprising a first portion adjacent to the under metal line having a first width in the first direction that is wider than a second width in the second direction.

### CROSS-REFERENCE TO RELATED APPLICATION

The present application claims the benefit of U.S. Provisional Patent Application Ser. No. 63/721,109, filed on Nov. 15, 2024, entitled AIR GAP STRUCTURE ON METAL LINE OF INTERCONNECT, the disclosure of which is hereby incorporated herein in its entirety by reference.

### BACKGROUND

The present disclosure generally relates to the field of integrated circuit devices and, more particularly, to back-end-of-line (BEOL) interconnect structures and methods of forming the same.

Back-end-of-line (BEOL) is a process in integrated circuit device fabrication that consists of depositing metal interconnect layers onto a wafer already patterned with devices. It is a second part of the integrated circuit device fabrication process after front-end-of-line (FEOL) processing is performed. In BEOL, the individual devices, e.g., transistors, capacitors, resistors, and the like are connected to each other in accordance with how the metal wiring is deposited. Parasitic capacitance may develop, however, between BEOL interconnects on the same or different vertical levels due in part to the dielectric constant of the insulating layer separating the interconnects being too high. In addition, leakage current can develop between interconnects on the same or different vertical levels.

### SUMMARY

An integrated circuit device, according to some embodiments, includes a first under mold layer and a second under mold layer each extending in a first direction and spaced apart from each other in a second direction, perpendicular to the first direction; an under metal line between the first under mold layer and the second under mold layer and extending in the first direction; an intermediate mold layer on the first under mold layer and the second under mold layer and separated from the under metal line by an air gap; and a via contact on the under metal line and extending through an opening in the intermediate mold layer, the via contact comprising a first portion adjacent to the under metal line having a first width in the first direction that is wider than a second width in the second direction.

A method, according to some embodiments, includes forming a pattern comprising a first under mold layer and a second under mold layer having an under metal line therebetween; forming an intermediate mold layer on the first under mold layer and the second under mold layer such that the intermediate mold layer is separated from the under metal line by an air gap; etching the intermediate mold layer to form a via opening therein; epitaxially growing a first portion of a via contact on the under metal line in the via opening; and depositing a second portion of the via contact on the first portion in the via opening.

### BRIEF DESCRIPTION OF THE DRAWINGS

FIG. 1A is a cross-sectional view of an integrated circuit device including an airgap extending on an axis of a metal line according to some embodiments of the disclosure;

FIG. 1B is a cross-sectional view of the integrated circuit device of FIG. 1A taken along line A-A′ of FIG. 1A;

FIGS. 2A-2G are cross-sectional views that illustrate methods of forming an integrated circuit device including an airgap extending on an axis of a metal line according to some embodiments of the disclosure;

FIG. 3 is a flowchart that illustrates operations associated with the cross-sectional views of FIGS. 2A-2G according to some embodiments of the disclosure; and

FIGS. 4A-4K are cross-sectional views that illustrate example operations of Front-End-Of-Line (FEOL) processing.

### DETAILED DESCRIPTION

Some embodiments stem from a realization that parasitic capacitance can develop between BEOL interconnects due at least in part to the dielectric constant of the insulating layer separating the upper and lower interconnects being too high. In addition, leakage current can develop between interconnect lines on the same or different vertical levels. Some embodiments of the disclosure may provide an integrated circuit device in which an air gap is formed that extends along an axis of a metal line. According to some embodiments of the disclosure, first and second under mold layers extend in a first direction and are spaced apart from each other in a second direction. An under metal line is between the first and second under mold layers and also extends in the first direction. An intermediate mold layer is formed on the first and second under mold layers using, for example, a selective deposition process, such as atomic layer deposition, or an epitaxial growth process. In the formation the formation of the intermediate mold layer, an air gap is formed over the under metal line that separates the intermediate mold layer from the under metal line. The air gap extends in the first direction along the axis of the metal line. An upper layer mold layer comprising a generally low dielectric constant material may be formed on the intermediate mold layer. Via patterning may be performed on the resulting structure to open a via over the under metal line. A via contact is then formed on the under metal line using a two stage process: in the first stage, a first portion of the via contact is formed through epitaxial growth on the under metal line; and in the second stage, a second portion of the via contact is formed on the first portion using atomic layer deposition. Due to the presence of the air gap, the first portion of the via contact may extend along the length of the under metal line so that the via contact has a wider width in the first direction along the length of the under metal line than in the second direction corresponding to the spacing direction between the under mold layers and the under metal line. In some embodiments, the via contact comprises molybdenum. After formation of the via contact, upper surfaces of the via contact and the upper mold layer may be planarized using, for example, chemical mechanical processing (CMP) process so that the upper surfaces of the via contact and upper mold layer are coplanar.

Advantageously, the air gap effectively decreases the dielectric constant between the one or more under metal lines and an upper metal contact thereby reducing parasitic capacitance. In addition, the air gap can reduce leakage current between one or more under metal lines and an upper metal contact and between under metal lines on the same vertical level or horizontal plane. As described above, the air gap allows the first portion of the via contact to extend along the length of the metal line. The increased contact surface area associated with this profile may lower resistivity between the via contact and the under metal line. The air gap may further improve etching efficiency when forming the via opening as there is less material to etch to ensure the under metal line is free of the upper mold layer and intermediate mold layer. Use of molybdenum for the via contact may provide generally low resistivity and also reduces diffusion, which can obviate the need for a liner material in the via opening. By eliminating the need for a liner in the via opening, the process of forming the via contact in the via opening is simplified. The two stage process of forming the via contact may provide the benefit of the accuracy of epitaxial growth to form the first portion of the via contact that extends along the under metal line in the air gap while further benefitting from the efficiency of using a deposition process, such as atomic layer deposition, to complete the second portion of the via contact on the first portion of the via contact. Embodiments of the disclosure may provide a self-aligned air gap formation technique in which an air gap tunnel is formed to reduce parasitic capacitance and leakage current while improving the efficiency of etching via openings due to a reduction in material to etch. The via contact formation process is improved using a combination of selective growth and atomic layer deposition by benefitting from both the accuracy of the selective growth operation and the efficiency of the atomic layer deposition process.

Front-End-Of-Line (FEOL) processing in semiconductor fabrication is the stage where the active devices of an integrated circuit are created directly on a substrate or wafer, such as, but not limited to, gallium arsenide, silicon carbide, sapphire, germanium, and/or gallium nitride. For purposes of illustration, example embodiments will be described with respect to a silicon substrate or wafer. The process begins with a polished silicon wafer, often lightly doped to form the base substrate. Isolation regions, typically formed using shallow trench isolation (STI), are etched and filled with oxide to electrically separate devices. Next, dopants are introduced by ion implantation to create n-wells and p-wells, which define the regions where NMOS and PMOS transistors will be built. Once the wells are in place, the gate stack is formed, starting with a thin gate oxide (traditionally SiO₂ or a high-k dielectric for advanced nodes), followed by deposition and patterning of polysilicon or metal gate material. Source and drain regions are then implanted on either side of the gate to form the active transistor channels, with sidewall spacers added to control diffusion and define extension implants. To reduce resistance, a silicidation step may be carried out, in which metals like nickel, cobalt, and/or titanium react with exposed silicon on the gate, source, and drain to form silicides. Finally, an interlayer dielectric is deposited to insulate the devices and prepare the wafer for the back-end-of-line (BEOL) stage, where multiple layers of metal interconnects are built to complete the integrated circuit.

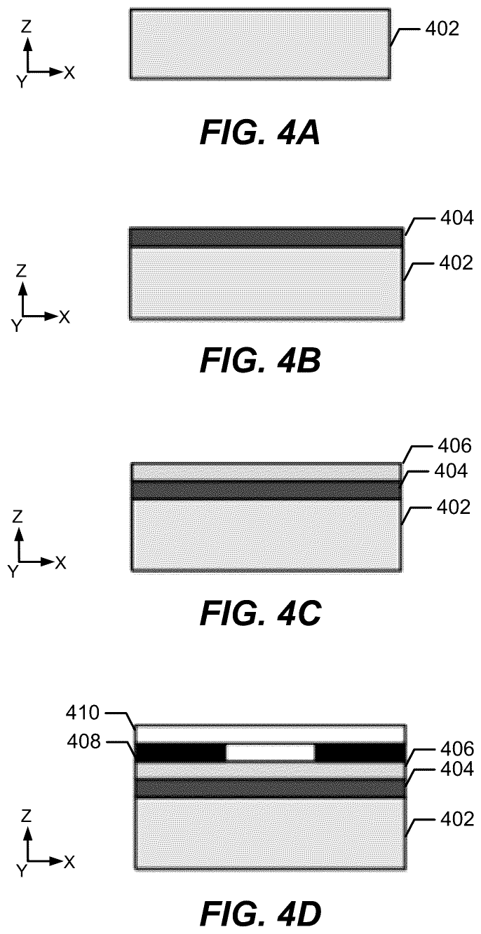

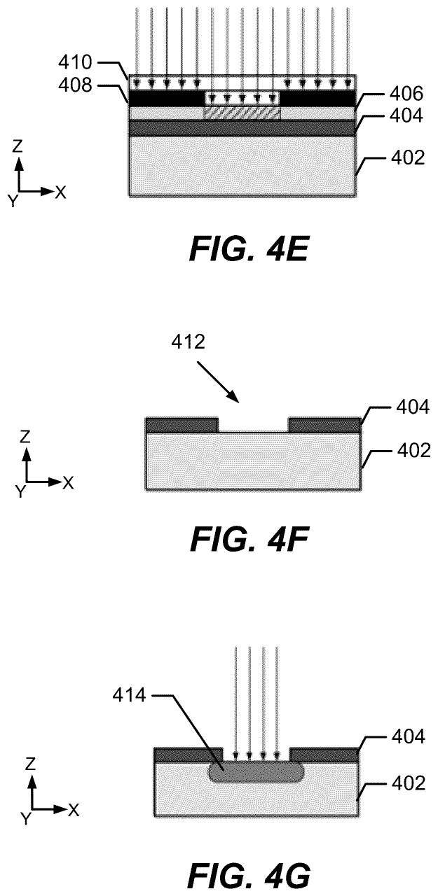

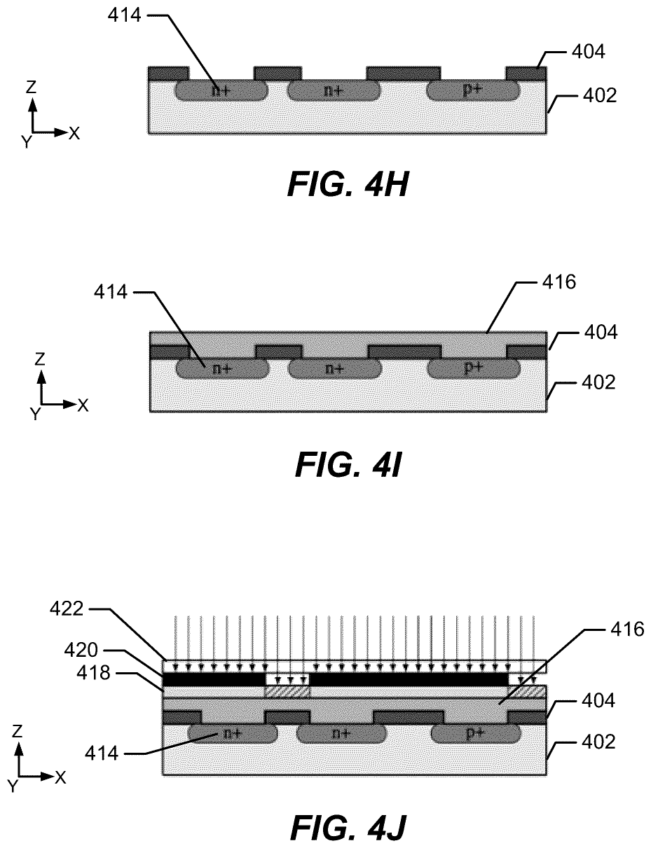

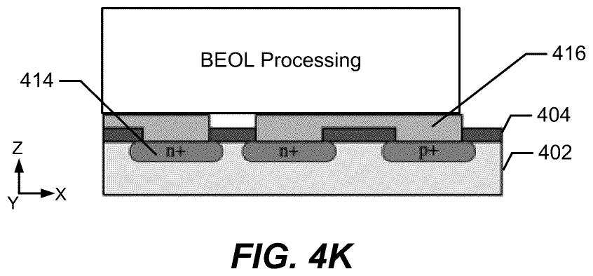

Example operations of FEOL processing are illustrated in the cross-sectional views of FIGS. 4A-4K. Referring to FIG. 4A, a mono-crystal silicon wafer 402, for example, is cleaned polished to obtain a substrate with its surface as regular and flat as possible. The cleaning is performed to ensure good adhesion of the photoresist material. Contaminants such as airborne particulates are controlled via clean rooms and most inorganic materials may be eliminated using chemicals or plasma stripping. In the case of absorbed water, a process called a dehydration bake is employed before the next step will take place. The top of the wafer 402 is then prepared for photolithography by covering it with an insulating layer 404 to serve as a mask, typically an oxide, as shown in FIG. 4B.

The process involves exposing the silicon (or other substrate material) layer to an oxidizing atmosphere at an elevated temperature. Usually steam or oxygen atmospheres are used. In the case of the steam atmosphere, the following reaction takes place, where silicon reacts with water forming the silicon dioxide and hydrogen gas:

$$Si + 2 H 2 O -> SiO 2 + 2 H 2$$

In the case of the oxygen atmosphere, silicon reacts with oxygen gas forming the silicon dioxide as show in the reaction below:

$$Si + O 2 -> SiO 2$$

Temperatures during this process are usually around 900° C. to 1300° C. By controlling the set temperature and the duration of the process, it is possible to predict the thickness of the oxide layers formed. From the equations above, it can be seen that silicon is consumed during the process. To achieve a specific thickness of the oxide layer, a layer of silicon approximately 0.44 times the thickness of the oxide layer may be used.

In other embodiment, Chemical Vapor Deposition (CVD) is a process in which thin films of silicon oxide, silicon nitride (Si3N4) and silicon are added to the substrate by means of chemical reactions or decomposition of gases. To form silicon oxide over layers that aren't silicon, a silicon compound such as silane (SiH4) is reacted with oxygen onto a heated substrate (usually around 425° C.), resulting in the following reaction:

$$SiH4 + O 2 -> SiO 2 + 2 H 2$$

Generally, the oxide film that is formed has bonding characteristics that are weaker than those achieved by thermal oxidation. Thus, CVD is typically only used when the substrate on which the film is to be created is not made of silicon, or when the operating temperatures of the thermal oxidation process exceed the tolerated requirements. Silicon nitride is used as a masking agent during oxidation processes because the formed layer of nitride has a lower oxidation rate compared to silicon. A CVD process for creating a nitride film involves reacting silane and ammonia (NH3) at around 800° C. for the following reaction:

$$3 SiH 4 + 4 NH 3 -> Si 4 N4 + 12 H 2$$

To help reduce the operating temperatures of the process, Plasma-enhanced CVD is used to reduce temperatures to around 300° C. CVD can also be used to deposit a layer of polycrystalline silicon (polysilicon) onto the wafer. Polysilicon is used as a conducting material for leads, gate electrodes in Metal-Oxide-Semiconductor (MOS) devices and contact material in shallow junction devices. This process involves reducing silane at high temperatures of about 600° C. as shown in the following reaction:

$$SiH 4 -> Si + 2 H 2$$

A related process to CVD is called “Epitaxial Deposition.” This involves growing an additional film as an extension of the same material on a substrate. Two methods for epitaxial deposition are “vapor-phase epitaxy” and molecular-beam epitaxy. In vapor-phase epitaxy, a process similar to CVD is used where silicon tetrachloride (SiCl4) is reduced by hydrogen gas in a highly controlled reaction, with temperatures reaching 1100° C. as shown in the following reaction:

$$SiCl 4 + 2 H 2 -> Si + 4 HCl$$

In the case of molecular-beam epitaxy, silicon with its dopants are vaporized and transported to the substrate in a vacuum chamber. Though it has the advantage of being carried out at low temperatures of around 400° C., it has a lower throughput than vapor-phase epitaxy and expensive equipment.

Referring to FIG. 4C, after formation of the insulating layer 404, a film of protective material, which is sensitive to light, called photoresist 406 is formed. In some embodiments, a uniform coating of photoresist 406 is applied by feeding a metered amount of liquid resist onto the center of the wafer and then spun on a turntable at a high speed, producing a uniform spread. This procedure is determined by a number of parameters including when the liquid is dispensed (static/dynamic), spin speeds, acceleration, volume, viscosity and time. The optimum conditions are found through experimental procedures. After coating, the resulting photoresist 406 film may be dried to remove excess solvent, promote adhesion, and harden the photoresist 406. As a result, the photoresist 406 may become less prone to particulate contamination because it becomes less tacky.

A photomask 408,410 with the circuit pattern for one layer of the chip is loaded and aligned with the wafer as shown in FIG. 4D. The photomask 408, 410 protects some of the substrate from exposure thus leaving those regions of photoresist 406 unprotected exposed. The photomask 408, 410 may be a thin, flat transparent glass having a thickness of about 2 mm with an opaque substance deposited in the desired regions of the photoresist 406 that are not to be exposed. The process of aligning the photomask 408,410 relative to the wafer before exposing the photoresist 406 leaving an image in the coated surface is generally a high precision process. The subsequent exposure depends primarily on two parameters: light intensity and time.

As shown in FIG. 4E, the exposure process of the wafer to intense UV light through the photomask 408, 410 allows for removal of the exposed photoresist 406 area. Referring to FIG. 4F, the unprotected insulating layer 404 material is then striped away using, for example, a chemical etching process and the remaining photoresist 406 is removed by a developer solution. In general, there are two types of photoresist: negative and positive. When exposed to UV light, the negative photoresist becomes polymerized and more difficult to dissolve in developer solution than the positive resist. For negative resist, the developer solution removes only the unexposed areas. In this way, it is possible to create a pattern of non-protected silicon wafer areas surrounded by regions of non-conducting material. Then, the modification of the electrical properties of the exposed areas involves doping processes, such as ion implantation which is used to create sources and drains 414 of one or more transistors as shown in FIG. 4G. The doping process involves accelerating vaporized ions of the dopant by an electric field and shooting them towards the substrate. These penetrate the substrate to a known average depth, which can be found from the voltage of the electrical field. This ability to know the average density of the dopant, along with the ability to carry out the process at room temperature are some of the main advantages over other techniques. The ion collisions, however, may damage the crystal structure of the substrate. This damage may be mitigated by annealing the wafer at temperatures of about 500° C. to 900° C., thus allowing the structure to repair itself. In some embodiments, the dopant may comprise ions of boron (B), phosphorus (P), and/or arsenic (As)

Other conducting or insulating layers may also be added. A new layer of material is added and the entire photolithography process, which includes imaging, deposition, etching, and doping, is repeated to create many different components of the chip, layer by layer.

Once all the active components of the IC are ready, the BEOL processing operations are performed to deposit the metal wiring between the individual devices to interconnect them, with a process called metallization. As shown in FIG. 4H after FEOL processing, one or more integrated circuit devices includes three well regions corresponding, for example, to source/drain regions 414. Common metals used in the metallization process include, but are not limited to, copper and aluminum, but many other metals may be applicable for use as metal interconnects at the nano-scale. The BEOL stage of chip fabrication may also include the formation of contacts and dielectric structures. BEOL processing generally begins when the first layer of a conducting metal 416 is deposited on top of the wafer as shown in FIG. 4I. Similar to the process described above with respect to FEOL processing, a layer of UV-sensitive photoresist 418 is added on the top of the metal 416. Then, in a manner similar to the processing of the components during the FEOL processing, a UV-light source is exposed to the photoresist 418 through a photomask 420, 422 defining the desired layout of the metal wires. The exposed section of the positive photoresist is then removed in the subsequent chemical etching step as shown in FIG. 4K. The etching process eliminates the unprotected metal to obtain a pattern of wires defined by the photomask 420, 422, which connects the different components of the chip. Most IC devices use more than one layer of wires to form all the necessary connections. In some chips, multiple layers are added in the BEOL process. Typically, metal interconnecting wires are isolated by dielectric layers to prevent the wires from creating a short circuit with other metal layers. The various metal layers are interconnected by etching holes, called vias, in the insulating material.

After the BEOL processing, the post-fab process is performed, which includes wafer testing, die separation, die testing, IC packaging, and final device testing.

Embodiments of the disclosure are described below that can reduce parasitic capacitance that can develop between interconnect lines formed during BEOL processing that may be due, at least in part, to the dielectric constant of the insulating layer separating upper and lower interconnects being too high as well as leakage current that can develop between interconnect lines on the same or different vertical levels.

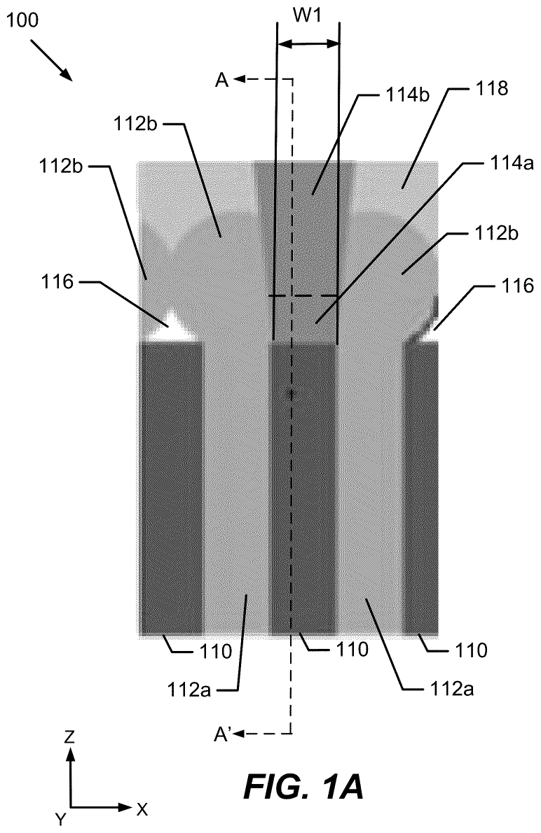

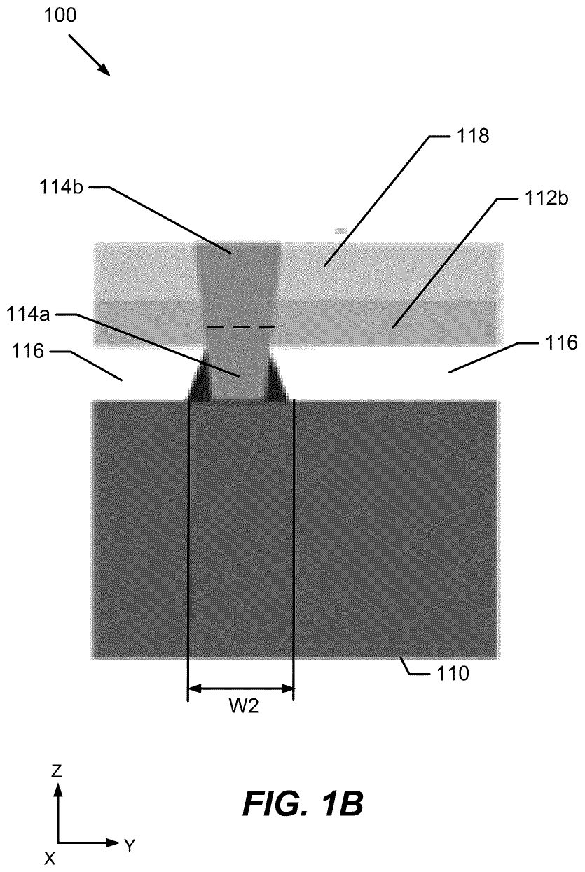

FIG. 1A is a cross-sectional view of an integrated circuit device including an airgap extending on an axis of a metal line according to some embodiments of the disclosure. FIG. 1B is a cross-sectional view of the integrated circuit device of FIG. 1A taken along line A-A′ of FIG. 1A.

Referring to FIGS. 1A and 1B, an integrated circuit device 100 including an airgap extending on an axis of a metal line includes under metal lines 110 spaced apart from each other in a second direction (X direction). The under metal lines 110 may comprise, according to some embodiments, aluminum, copper, cobalt, and/or ruthenium. The under metal lines 110 have under mold layers 112a therebetween. An intermediate mold layer 112b is on the under mold layers 112a and is separated from the under metal lines 110 via respective air gaps 116. As shown in FIG. 1B, the air gap 116 extends along an axis of an under metal line 110 in a first direction (Y direction) providing separation between the under metal line 110 and the intermediate mold layer 112b. An upper mold layer 118 is on the intermediate mold layer 112b. According to some embodiments, the intermediate mold layer 112b and the upper mold layer 118 may comprise silicon dioxide, fluorinated silicate glass, an organosilicate glass, and/or a spin-on polymer. A via opening is formed in the intermediate mold layer 112b and the upper mold layer 118 and a via contact is formed therein. The via contact includes a first portion 114a that is formed in the via opening by, for example, epitaxial growth. This allows for the formation of a wider contact area with the under metal line 110 as shown in FIG. 1B as the first portion 114a of the via contact can extend into the air gap 116 illustrated by a skirt profile. As a result, the first portion 114a of the via contact has a width W2 in the first direction (Y direction) that is greater than a width W1 in the second direction (X direction). Once the first portion 114a of the via contact is formed, the second portion 114b of the via contact is formed using, for example, atomic layer deposition. Advantageously, atomic layer deposition may be more efficient than epitaxial growth allowing for improved efficiency in forming the via contact. In some embodiments, the via contact comprises molybdenum, which provides generally low resistivity and also inhibits diffusion.

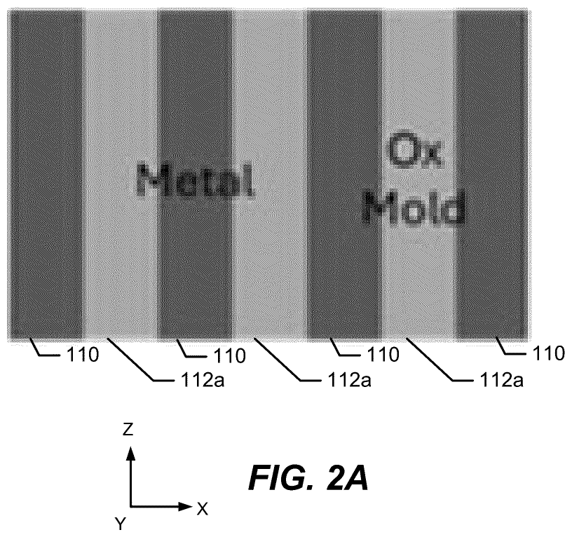

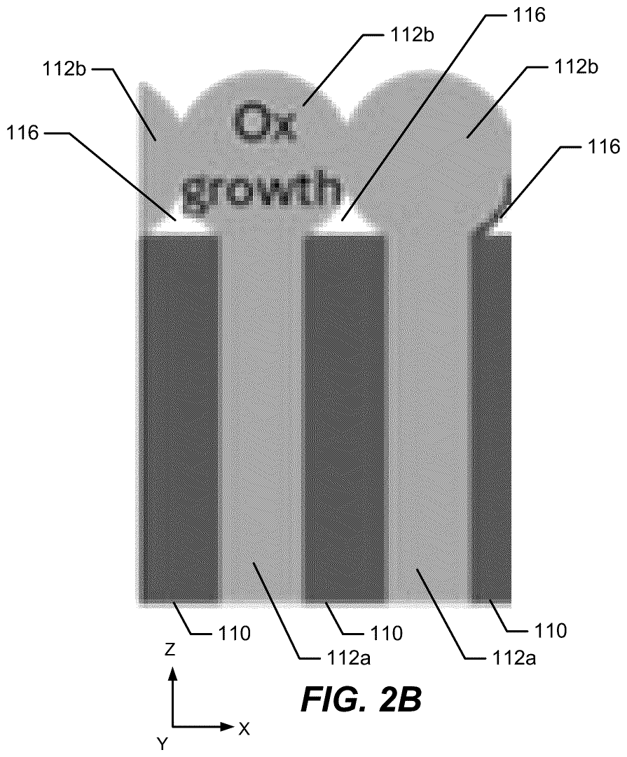

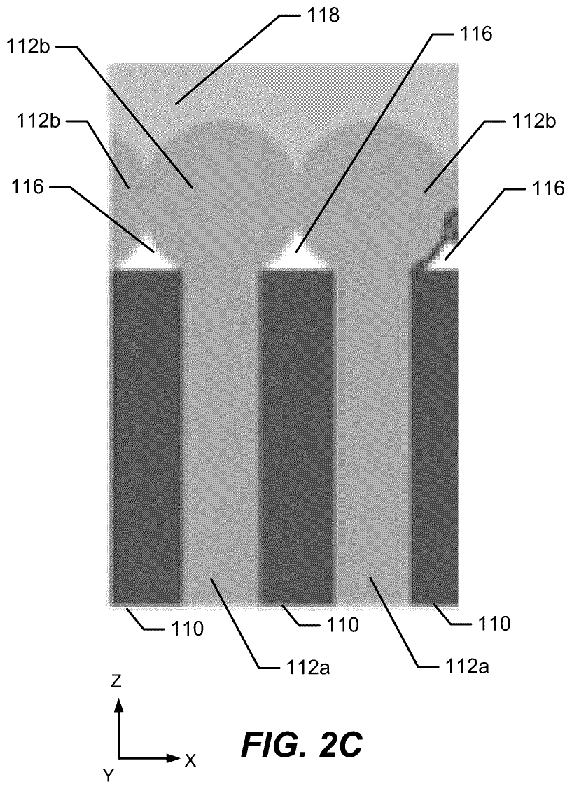

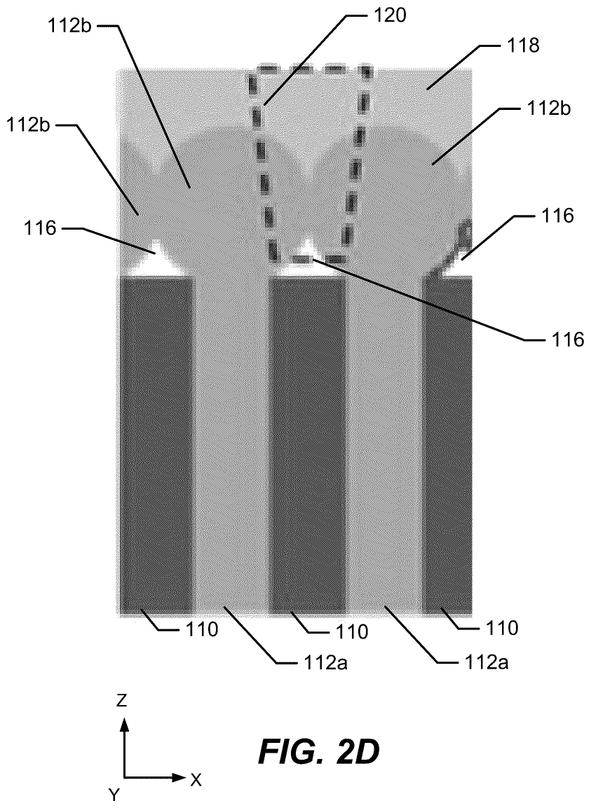

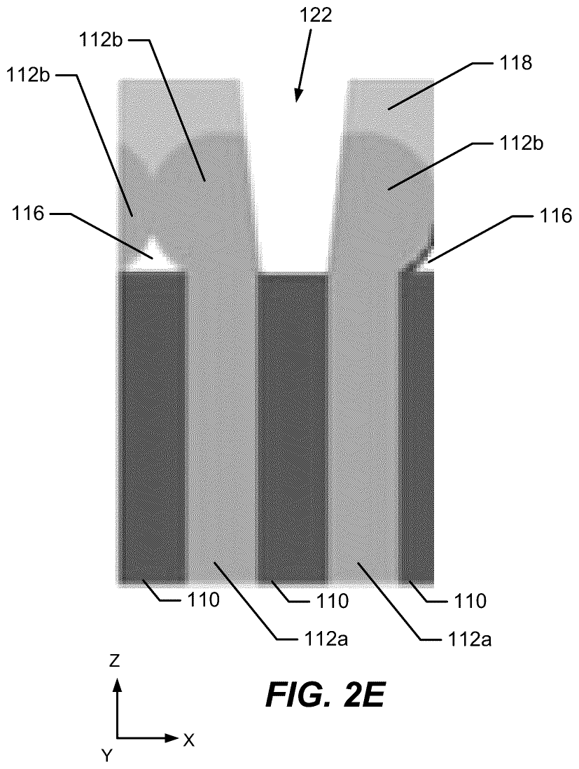

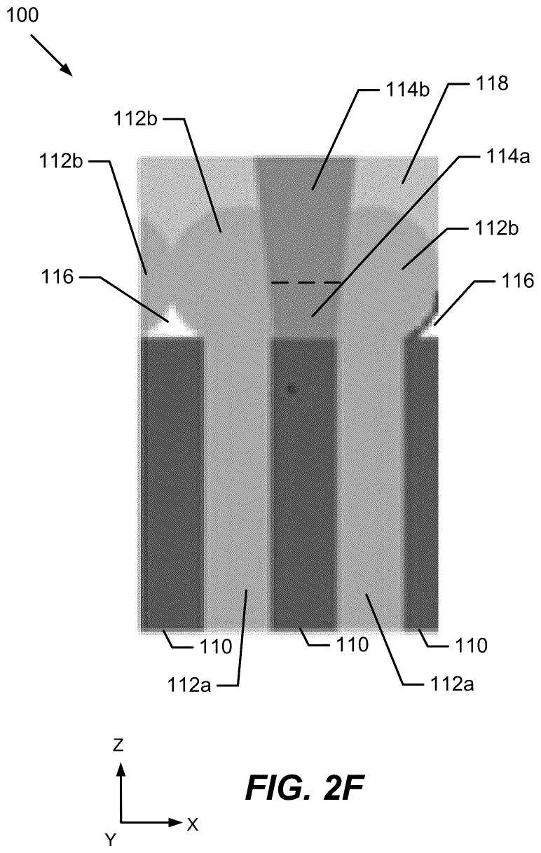

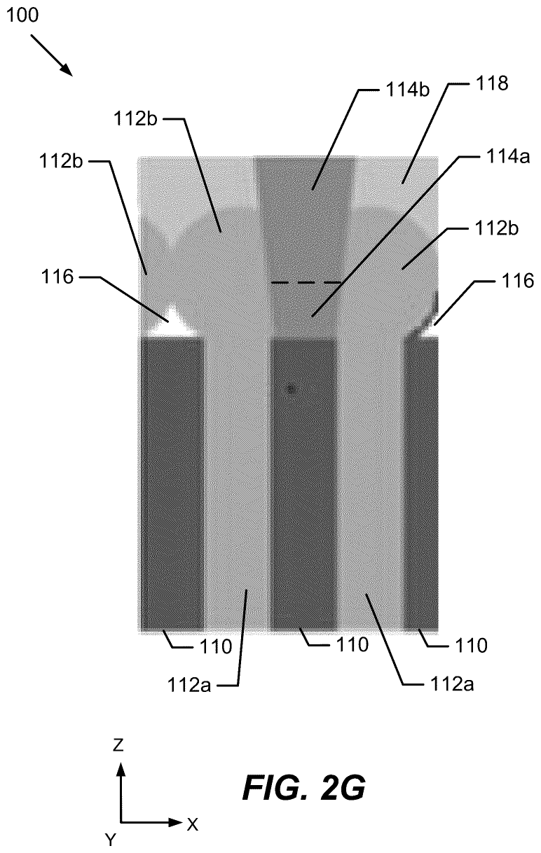

FIGS. 2A-2G are cross-sectional views that illustrate methods of forming an integrated circuit device including an airgap extending on an axis of a metal line according to some embodiments of the disclosure.

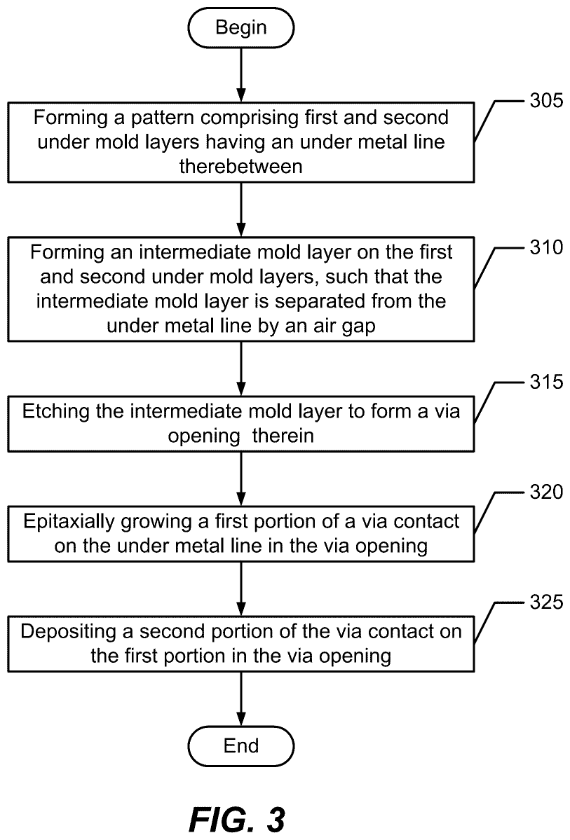

A method of forming an integrated circuit device 100 including an airgap extending on an axis of a metal line, according to some embodiments of the disclosure, will be described with respect to FIGS. 2A-2G and FIG. 3. Referring now to FIG. 2A, a pattern is formed comprising under metal lines 110 with under mold layers 112a between adjacent under metal lines 110 in the X direction. Referring to FIG. 2B, an intermediate mold layer 112b is formed on the under mold layers 112a and is separated from the under metal lines 110 via respective air gaps 116. The intermediate mold layer 112b may be formed using a variety of selective deposition or growth techniques in accordance with different embodiments of the disclosure. In some embodiments, the intermediate mold layer 112b may be formed using epitaxial growth and in other embodiments the intermediate mold layer 112b may be formed using atomic layer deposition. Referring to FIG. 2C, an upper mold layer 118 comprising a material having a relatively low dielectric constant, such as silicon dioxide, fluorinated silicate glass, an organosilicate glass, and/or a spin-on polymer, is deposited on the intermediate mold layer 112b. In some embodiments, the upper mold layer 118 is deposited using chemical vapor deposition. Referring to FIG. 2E, a via opening may be created to form a via contact therein on an under metal line 110. The placement of the via opening is illustrated by the dashed lines, which marks the region to be etched 120. As can be seen in FIG. 2E, the presence of the air gap 116 over the under metal line 110 reduces the amount of etching required to remove the intermediate mold layer 112b and the upper mold layer 118 to form the via opening. Referring to FIG. 2F, structure of FIG. 2E is masked to expose the region 120 and the upper mold layer 118 and the intermediate mold layer 112b are etched using, for example, a dry etching process to form a via opening 122. Referring to FIG. 2G, a via contact is formed in the via opening 122. In some embodiments, formation of the via contact comprises a two stage process. In the first stage, a first portion 114a of the via contact is formed in the via opening by, for example, epitaxial growth. As described above with respect to FIG. 1B, this allows for the formation of a wider contact area with the under metal line 110 as the first portion 114a of the via contact can extend into the air gap 116. After formation of the first portion 114a of the via contact, the second portion 114b of the via contact is formed on the first portion 114a using, for example, atomic layer deposition. As described above, atomic layer deposition may be more efficient than epitaxial growth allowing for improved efficiency in forming the via contact. In some embodiments, the via contact comprises molybdenum, which provides generally low resistivity and also inhibits diffusion. As shown in FIG. 2G, after formation of the via contact, the upper surfaces of the second portion 114b of the via contact and the upper mold layer may be planarized so that they are coplanar.

FIG. 3 is a flowchart that illustrates operations associated with the cross-sectional views of FIGS. 2A-2G according to some embodiments of the disclosure. Referring now to FIG. 3, operations begin at block 305, where a pattern is formed comprising first and second under mold layers 112a having an under metal line 110 therebetween. Such embodiments are illustrated in FIG. 2A. The under metal lines 110 may comprise, according to some embodiments, aluminum, copper, cobalt, and/or ruthenium. An intermediate mold layer 112b is formed on the first and second under mold layers 112a, such that the intermediate mold layer 112b is separated from the under metal line 110 by an air gap 116 at block 310. Such embodiments are illustrated in FIG. 2B. The intermediate mold layer 112b may comprise silicon dioxide, fluorinated silicate glass, an organosilicate glass, and/or a spin-on polymer. The intermediate mold layer 112b may be formed using epitaxial growth and in other embodiments the intermediate mold layer 112b may be formed using atomic layer deposition. The intermediate mold layer 112b is etched at block 315 to form a via opening 122 therein. Such embodiments are illustrated in FIGS. 2E and 2F. The presence of the air gap 116 over the under metal line 110 reduces the amount of etching required to remove the intermediate mold layer 112b and the upper mold layer 118 to form the via opening. The etching process may be performed, for example, using a dry etching process. A first portion 114a of a via contact is epitaxially grown on the under metal line 110 in the via opening 122 at block 320 as shown in FIG. 2G. A second portion 114b of the via contact is deposited on the first portion 114a of the via contact in the via opening 122 at block 325 as shown in FIG. 2G. In some embodiments, formation of the first portion 114a and the second portion 114b of the via contact comprises a two stage process. In the first stage, the first portion 114a of the via contact maybe formed in the via opening by, for example, epitaxial growth. Epitaxial growth may provide improved accuracy in forming the first portion 114a of the via contact that provides an interface with the under metal line 110. As described above with respect to FIG. 1B, the extended air gap may allow for the formation of a wider contact area with the under metal line 110. The wider contact area is a result of the first portion 114a of the via contact extending into the air gap 116. After formation of the first portion 114a of the via contact, the second portion 114b of the via contact is formed on the first portion 114a using, for example, atomic layer deposition. Atomic layer deposition may be more efficient than epitaxial growth allowing for improved efficiency in forming the via contact. Thus, the two stage process of forming the via contact takes advantage of both the accuracy of selective growth and the efficiency of atomic layer deposition. In some embodiments, the via contact comprises molybdenum, which provides generally low resistivity and also inhibits diffusion. As a result, a liner is not needed between the via contact and the under metal line 110, which further improves the efficiency in the process of forming the via contact.

Some embodiments of the disclosure may provide an integrated circuit device and method of forming the same having an airgap that extends along an axis of a metal line for improving interconnect performance characteristics as set forth in the following examples: Example 1: an integrated circuit device, comprises: a first under mold layer and a second under mold layer each extending in a first direction and spaced apart from each other in a second direction, perpendicular to the first direction; an under metal line between the first under mold layer and the second under mold layer and extending in the first direction; an intermediate mold layer on the first under mold layer and the second under mold layer and separated from the under metal line by an air gap; and a via contact on the under metal line and extending through an opening in the intermediate mold layer, the via contact comprising a first portion adjacent to the under metal line having a first width in the first direction that is wider than a second width in the second direction.

Example 2: the integrated circuit device of Example 1, further comprising: an upper mold layer on the intermediate mold layer.

Example 3: the integrated circuit device of Example 2, wherein the upper mold layer comprises silicon dioxide, fluorinated silicate glass, an organosilicate glass, or a spin-on polymer.

Example 4: the integrated circuit device of any of Examples 2-3, wherein an upper surface of the upper mold layer and an upper surface of the via contact are coplanar.

Example 5: the integrated circuit device of any of Examples 1-4, wherein the under metal line comprises aluminum, copper, cobalt, or ruthenium.

Example 6: the integrated circuit device of any of Examples 1-5, wherein the intermediate mold layer comprises silicon dioxide, fluorinated silicate glass, an organosilicate glass, or a spin-on polymer.

Example 7: the integrated circuit device of any of Examples 1-6, wherein the via contact comprises molybdenum.

Example 8: a method, comprises: forming a pattern comprising a first under mold layer and a second under mold layer having an under metal line therebetween; forming an intermediate mold layer on the first under mold layer and the second under mold layer such that the intermediate mold layer is separated from the under metal line by an air gap; etching the intermediate mold layer to form a via opening therein; epitaxially growing a first portion of a via contact on the under metal line in the via opening; and depositing a second portion of the via contact on the first portion in the via opening.

Example 9: the method of Example 8, wherein depositing the second portion of the via contact comprises: depositing the second portion of the via contact on the first portion in the via opening by atomic layer deposition.

Example 10: the method of any of Examples 8-9, wherein forming the intermediate mold layer comprises: forming the intermediate mold layer on the first under mold layer and the second under mold layer by epitaxial growth.

Example 11: the method of any of Examples 8-9, wherein forming the intermediate mold layer comprises: forming the intermediate mold layer on the first under mold layer and the second under mold layer by atomic layer deposition.

Example 12: the method of any of Examples 8-11, wherein the first under mold layer and the second under mold layer extend in a first direction and are spaced apart from each other in a second direction, perpendicular to the first direction, wherein the under metal line extends in the first direction, and wherein the first portion has a first width in the first direction that is wider than a second width in the second direction.

Example 13: the method of any of Examples 8-12, further comprising: depositing an upper mold layer on the intermediate mold layer before etching the intermediate mold layer.

Example 14: the method of any of Example 13, wherein etching the intermediate mold layer comprises: etching the intermediate mold layer and the upper mold layer to form the via opening therein.

Example 15: the method of any of Examples 13-14, further comprising: planarizing upper surfaces of the upper mold layer and the via contact so that the upper surfaces of the upper mold layer and the via contact are coplanar.

Example 16: the method of any of Examples 13-15, wherein depositing the upper mold layer comprises: depositing the upper mold layer using chemical vapor deposition.

Example 17: the method of any of Examples 13-16, wherein the upper mold layer comprises silicon dioxide, fluorinated silicate glass, an organosilicate glass, or a spin-on polymer.

Example 18: the method of any of Examples 8-17, wherein the via contact comprises molybdenum.

Example 19: the method of any of Examples 8-18, wherein the under metal line comprises aluminum, copper, cobalt, or ruthenium.

Example 20: the method of any of Examples 8-19: wherein the intermediate mold layer comprises silicon dioxide, fluorinated silicate glass, an organosilicate glass, or a spin-on polymer.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout the description. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

It should also be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present invention.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “connected” or “on,” another element, it can be directly connected or on, the other element, or intervening elements may also be present. In contrast, when an element is referred to as being “directly connected” or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present inventive concept. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device, comprising:
a first under mold layer and a second under mold layer each extending in a first direction and spaced apart from each other in a second direction, perpendicular to the first direction;
an under metal line between the first under mold layer and the second under mold layer and extending in the first direction;
an intermediate mold layer on the first under mold layer and the second under mold layer and separated from the under metal line by an air gap; and
a via contact on the under metal line and extending through an opening in the intermediate mold layer, the via contact comprising a first portion adjacent to the under metal line having a first width in the first direction that is wider than a second width in the second direction.

2. The integrated circuit device of claim 1, further comprising:
an upper mold layer on the intermediate mold layer.

3. The integrated circuit device of claim 2, wherein the upper mold layer comprises silicon dioxide, fluorinated silicate glass, an organosilicate glass, or a spin-on polymer.

4. The integrated circuit device of claim 2, wherein an upper surface of the upper mold layer and an upper surface of the via contact are coplanar.

5. The integrated circuit device of claim 1, wherein the under metal line comprises aluminum, copper, cobalt, or ruthenium.

6. The integrated circuit device of claim 1, wherein the intermediate mold layer comprises silicon dioxide, fluorinated silicate glass, an organosilicate glass, or a spin-on polymer.

7. The integrated circuit device of claim 1, wherein the via contact comprises molybdenum.

8. A method, comprising:
forming a pattern comprising a first under mold layer and a second under mold layer having an under metal line therebetween;
forming an intermediate mold layer on the first under mold layer and the second under mold layer such that the intermediate mold layer is separated from the under metal line by an air gap;
etching the intermediate mold layer to form a via opening therein;
epitaxially growing a first portion of a via contact on the under metal line in the via opening; and
depositing a second portion of the via contact on the first portion in the via opening.

9. The method of claim 8, wherein depositing the second portion of the via contact comprises:
depositing the second portion of the via contact on the first portion in the via opening by atomic layer deposition.

10. The method of claim 8, wherein forming the intermediate mold layer comprises:
forming the intermediate mold layer on the first under mold layer and the second under mold layer by epitaxial growth.

11. The method of claim 8, wherein forming the intermediate mold layer comprises:
forming the intermediate mold layer on the first under mold layer and the second under mold layer by atomic layer deposition.

12. The method of claim 8, wherein the first under mold layer and the second under mold layer each extend in a first direction and are spaced apart from each other in a second direction, perpendicular to the first direction,
wherein the under metal line extends in the first direction, and
wherein the first portion has a first width in the first direction that is wider than a second width in the second direction.

13. The method of claim 8, further comprising:
depositing an upper mold layer on the intermediate mold layer before etching the intermediate mold layer.

14. The method of claim 13, wherein etching the intermediate mold layer comprises:
etching the intermediate mold layer and the upper mold layer to form the via opening therein.

15. The method of claim 14, further comprising:
planarizing upper surfaces of the upper mold layer and the via contact so that the upper surfaces of the upper mold layer and the via contact are coplanar.

16. The method of claim 13, wherein depositing the upper mold layer comprises:
depositing the upper mold layer using chemical vapor deposition.

17. The method of claim 13, wherein the upper mold layer comprises silicon dioxide, fluorinated silicate glass, an organosilicate glass, or a spin-on polymer.

18. The method of claim 8, wherein the via contact comprises molybdenum.

19. The method of claim 8, wherein the under metal line comprises aluminum, copper, cobalt, or ruthenium.

20. The method of claim 8, wherein the intermediate mold layer comprises silicon dioxide, fluorinated silicate glass, an organosilicate glass, or a spin-on polymer.
